(19) United States
(12) Patent Application Publication
(10) Pub. No.: US 2006/0219863 A1
(43) Pub. Date: Oct. 5, 2006

(54) Obtaining data from a utility meter using image-based movement tracking

(76) Inventors: Jefferson B. Burch, Palo Alto, CA (US); Gary Gordon, Saratoga, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 11/078,831

(22) Filed: Mar. 11, 2005

(51) Int. Cl. H01L 27/00

(52) U.S. Cl. 250/208.1

(57) ABSTRACT

Power data is obtained from a power meter that utilizes a rotatable element (e.g., a disk) by illuminating a spot on the rotatable element, capturing image information from the surface of the rotatable element, processing the image information to track movement of the rotatable element, and converting the movement information to digital power data. Movement of the rotatable element is tracked by capturing successive frames of image information and correlating common features in the image frames to determine the magnitude of movement of the common features.

### BACKGROUND OF THE INVENTION

There is a growing desire to be able to centrally monitor and control the use of electrical power in real-time, especially the residential use of power. Real-time control of power usage is particularly helpful in times of energy shortages or during peak demand periods. Real-time monitoring of power usage by a central monitoring station can be accomplished relatively easily with new solid-state power meters. However, there is currently such a large installed base of induction-type power meters at residences that replacing these meters would be an extremely costly endeavor.

Induction-type power meters rely on magnetic flux, which is proportional to the amount of power consumed, to turn a rotatable element (e.g., a disk). A mechanical register counts the revolutions of the rotatable element and the number of revolutions is converted to a measure of consumed power (e.g., as kilowatt-hours). The measure of power is then manually read from the register (e.g., from a series of dials or a cyclometer) on a regular basis for billing purposes.

Various retrofit systems have been developed for induction-type power meters to translate meter information into digital information that can be automatically communicated to a central monitoring station. In particular, there are various techniques that use optical systems to track the number of revolutions of a meter's rotatable element. These optical systems generally involve a light source, a photodetector, and some modification to the rotatable element to track the number of revolutions the rotatable element makes. For example, a portion of the rotatable element may be modified with a reflective wedge that causes a detectable reflection of light each revolution. Another implementation involves making a hole in the rotatable element and aligning the light source and photodetector such that a beam of light passes through the hole and is detected once per revolution. A limitation to these solutions is that modifying the rotatable element adds complexity to the installation process. Additionally, with these systems it is difficult to resolve the direction of the rotatable element rotation, which is an important consideration in cases where power is both consumed and generated.

### SUMMARY OF THE INVENTION

In accordance with the invention, power data is obtained from a power meter that utilizes a rotatable element (e.g., a disk or cylinder) by illuminating a spot on the rotatable element, capturing image information from the surface of the rotatable element, processing the image information to track movement of the rotatable element, and converting the movement information to digital power data. Movement of the rotatable element is tracked by capturing successive frames of image information and correlating common features in the image frames to determine the magnitude of movement of the common features. Because the power data is in digital form, it can be readily communicated to a central monitoring station using known communications systems.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 depicts portions of a single phase induction-type power meter and a retrofit system.

FIG. 2 depicts the disk and an expanded view of an embodiment of the retrofit system from FIG. 1.

FIG. 3 depicts an example of an IC chip that includes an image sensor, a tracking engine, and conversion logic.

FIG. 4A is a front view of a power meter and a retrofit system that is attached to the outside of the glass cover of the power meter.

FIG. 4B is a side view of the power meter from FIG. 4A that depicts the retrofit system attached to the outside of the glass cover of the power meter.

FIG. 5A is a front view of a power meter and a retrofit system that is attached to the inside of the glass cover of the power meter.

FIG. 5B is a side view of the power meter from FIG. 5A that depicts the retrofit system attached to the inside of the glass cover of the power meter.

FIG. 6 is a process flow diagram of a method for obtaining data from a power meter that utilizes rotation of a disk to measure power in accordance with the invention.

### DETAILED DESCRIPTION

Power data is obtained from a power meter that utilizes a rotating disk by illuminating a spot on the disk, capturing image information from the surface of the disk, processing the image information to track movement of the disk, and converting the movement information to digital power data. Movement of the disk is tracked by capturing successive frames of image information and correlating common features in the image frames to determine the magnitude of movement of the common features.

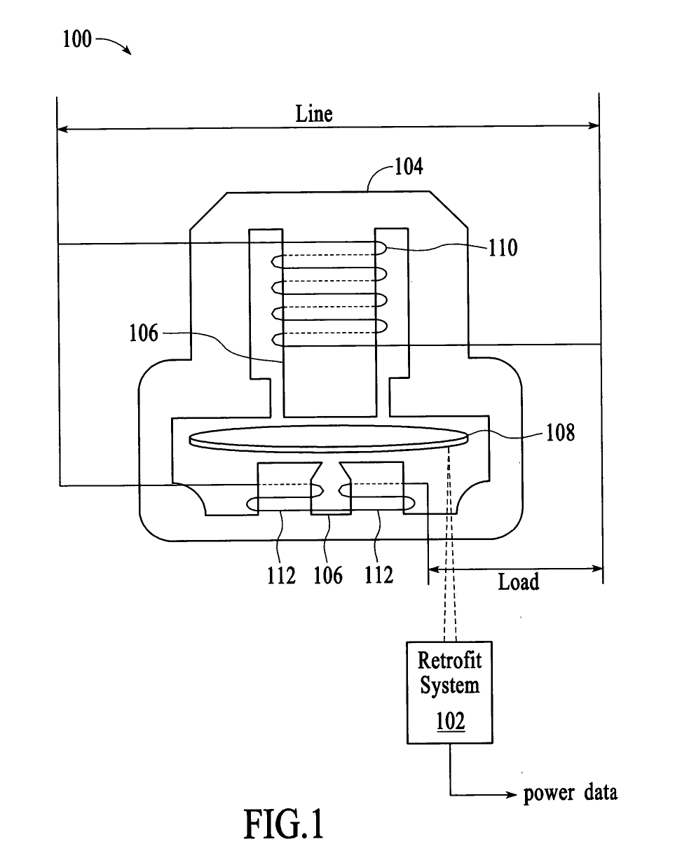

In accordance with an embodiment of the invention, FIG. 1 depicts portions of a single phase induction-type power meter 100 and a retrofit system 102. The portions of the induction-type power meter that are depicted include a frame 104, a stator 106 (also referred to as an element), a rotatable element 108, a voltage coil 110, and a current coil 112. As depicted in FIG. 1, the current coil is connected in series with the load and the voltage coil is connected across the line and carries a current proportional to the voltage of the circuit. When electricity is consumed, the voltage and current create a magnetic flux that causes the disk to rotate. Mechanical elements of a register (not shown) translate the rotation of the disk into changes in meter readings. The rotatable element may be embodied as, for example, a disk or a cylinder. Throughout the description, the rotatable element is referred to and depicted as a disk but it should be understood that the disk may be replaced by a cylinder, sphere or other suitable shape in accordance with the invention.

The retrofit system 102 measures power by illuminating a spot on the surface of the disk 108, capturing image information from the surface of the disk, processing the image information to track movement of the disk, and converting the movement information to digital power data. Because power data is in digital form, it can be readily communicated to a central monitoring station using known communications systems. As is described in more detail below, movement of the disk is tracked by capturing successive frames of image information and correlating common features in the image frames to determine the magnitude of movement of the common features. To accomplish image-based tracking of disk movements, the retrofit system is oriented with respect to the disk such that a beam of light from the retrofit system illuminates a spot on the disk and such that light reflected from the illuminated spot is detected by the retrofit system.

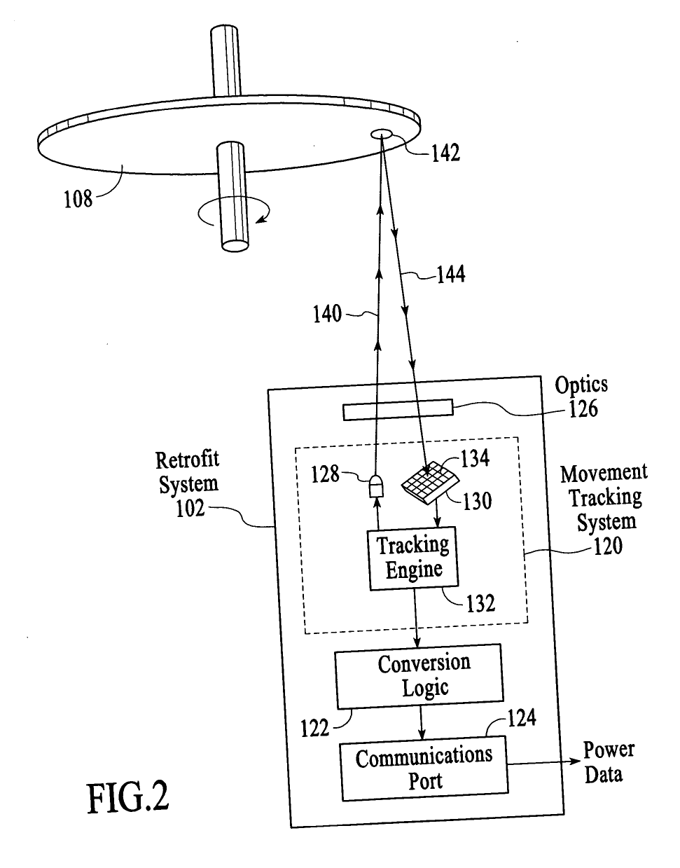

FIG. 2 depicts the disk 108 and an expanded view of an embodiment in accordance with the invention of the retrofit system 102 from FIG. 1. The retrofit system includes a movement tracking system 120, conversion logic 122, a communications port 124, and optics 126. The movement tracking system includes a light source 128, an image sensor 130, and a tracking engine 132.

The light source 128 of the movement tracking system 120 provides a beam of light 140 that is directed to illuminate a spot 142 on the surface of the disk 108. In the embodiment of FIG. 2, the light source is a light emitting diode (LED) although other light sources are possible. The light source may be pulsed or emit a continuous beam of light depending on the application.

The image sensor 130 is an array of distinct photodetectors, for example, a 16×16 or 32×32 array of distinct photodetectors 134 configured to detect light that is reflected from the illuminated spot 142 on the disk 108. Each of the photodetectors in the array generates light intensity information that is output as a digital value (e.g., an 8-bit digital value). Image information is captured in frames, where a frame of image information includes a set of simultaneously captured values for each distinct photodetector in the array. The disks used in induction-type power meters are often made of a metal such as aluminum and have surface features, which when illuminated, can be picked up by the image sensor. Image frames captured by the image sensor include data that represents features on the surface of the corresponding disk. The rate of image frame capture is programmable and, for example, ranges up to 2,300 frames per second. In an embodiment in accordance with the invention, the image sensor has a resolution of 800 characters per inch (cpi).

The tracking engine 132 compares successive image frames to determine the movement of image features between frames. In particular, the tracking engine determines movement by correlating common features that exist in successive image frames. The movement between image frames is expressed in terms of movement vectors in, for example, X and Y directions (e.g., ΔX and ΔY). The movement vectors are then used to determine the rotational movement of the disk 108. More detailed descriptions of exemplary image-based movement tracking techniques are provided in U.S. Pat. No. 5,644,139, entitled NAVIGATION TECHNIQUE FOR DETECTING MOVEMENT OF NAVIGATION SENSORS RELATIVE TO AN OBJECT, and U.S. Pat. No. 6,222,174, entitled METHOD OF CORRELATING IMMEDIATELY ACQUIRED AND PREVIOUSLY STORED FEATURE INFORMATION FOR MOTION SENSING, both of which are assigned to the assignee of the current invention and incorporated by reference herein.

Using the movement vectors that are generated by correlating common features, the tracking engine 132 can track the actual distance traveled by the disk 108 with a resolution below one revolution instead of just counting the number of revolutions, as is the case in many other optical tracking systems. Additionally, the movement vectors include direction information, which allows the direction of the disk's rotation to be accurately tracked. Rotational direction is important in cases where power consumption and power generation are measured by the same meter. In these situations, power consumption causes the disk to rotate in one direction while power generation causes the disk to rotate in the opposite direction.

The tracking engine 132 may also include logic to control the light source 128. For example, the tracking engine may include logic to pulse the light source on or to turn the light source off during periods of no disk movement. In one embodiment, the light source is turned off after some period of no disk movement and then periodically turned on so that the movement tracking system can check for disk movement.

The conversion logic 122 converts disk movement information from the tracking engine 132 into digital power data. As is known in the field, induction-type power meters have a measurement constant that is used to convert disk rotations to power data. The typical measurement constant, often referred to as the “disk constant,” K_{H}, is the number of kilowatt-hours per disk revolution. The disk constant can be calculated by applying a known amount of power to the meter and counting the number of revolutions the disk makes. The applied load divided by the number of revolutions gives the disk constant. The disk constant is usually printed on the name plate of a meter. In an embodiment in accordance with the invention, the conversion logic is programmed with the disk constant and the disk constant and movement information are used to generate the digital power data for a meter. In an exemplary calculation, the disk constant is divided by the linear distance of one disk revolution at the illuminated spot to calculate the number of kilowatt-hours per unit of movement. This value is referred to herein as the conversion constant. To produce power data, the conversion constant is multiplied by the tracked movement of the disk.

The communications port 124 enables the retrofit system 102 to communicate the digital power data to another device, for example, a central monitoring station. The communications port can be any type of wired or wireless communications port that supports the communication of digital power data. Examples of the communications port include a wireless transmitter or transceiver, an RS-232 jack, an RJ-45 jack, and a Universal Serial Bus (USB) connector.

The optics 126 manipulate the transmitted optical beam 140 to illuminate a spot 142 on the disk and to focus reflected light 144 from the illuminated spot onto the image sensor 130. The optics are implementation specific and may be applied to the transmitted portion of the beam, the reflected portion of the beam, or the both portions of the beam. The optics may include a combination of optical devices including, for example, lenses and reflectors. In order for movement tracking to be effective, the reflected light must be focused onto the image sensor. In an embodiment, the optics include a lens that is configured and positioned to focus an image of the illuminated spot onto the image sensor. The focal point of a lens is a function of the lens itself and the distance between the lens and the object to be imaged. The details of the optics design are highly dependent on how and where the retrofit system is mounted in relation to the disk. It should be understood that many design configurations can be implemented without deviating from the scope of the invention, which is defined by the claims. In some instances, optics may not be necessary.

In an embodiment in accordance with the invention of FIGS. 1 and 2, the retrofit system 102 is oriented with respect to the disk 108 to illuminate a spot 142 on the bottom of the disk. In an alternative embodiment in accordance with the invention, the retrofit system can be oriented with respect to the disk to illuminate a spot on the top of the disk or on the edge of the disk. The exact location of the illuminated spot is implementation specific.

Another design consideration is the location of the illuminated spot 142 relative to the center of the disk. In particular, the further the illuminated spot is from the center of the disk 108, the faster the disk passes through the illuminated spot. The speed of the disk and the rate of image capture must be such that common image features are captured in sequential frames. If the disk is rotating past the illuminated spot so fast that no common features appear in successive image frames, the correlation algorithm cannot produce valid movement information. As a result, the rotational speed of the disk must be considered when selecting the location of he illuminated spot and the rate of image capture. In some cases, the image capture rate and/or the processing speed may be a limiting factor in selecting the location of the illuminated spot.

Operation of the retrofit system 102 is described with reference to FIG. 2. When power is either consumed or generated, a magnetic flux is generated that causes the disk 108 to rotate. As the disk rotates, the light source 128 generates a beam of light that illuminates a spot 142 on the disk. Some of the light that illuminates the spot on the disk is reflected back towards the retrofit system. The optics 126 focus the reflected light so that a focused image is incident on the image sensor 130. The image sensor captures successive frames of image information. The image frames are correlated by the tracking engine 132 to determine movement of the disk. In particular, movement of the disk is determined by correlating common features that exist in successive image frames. Movement information generated by the tracking engine is provided to the conversion logic 122, where it is converted into digital power data. For example, the movement information is converted into kilowatt-hours consumed or generated. The digital power data is communicated to a monitoring station via the communications port 124. The digital power data may be communicated, for example, at regular intervals or upon request from a monitoring station.

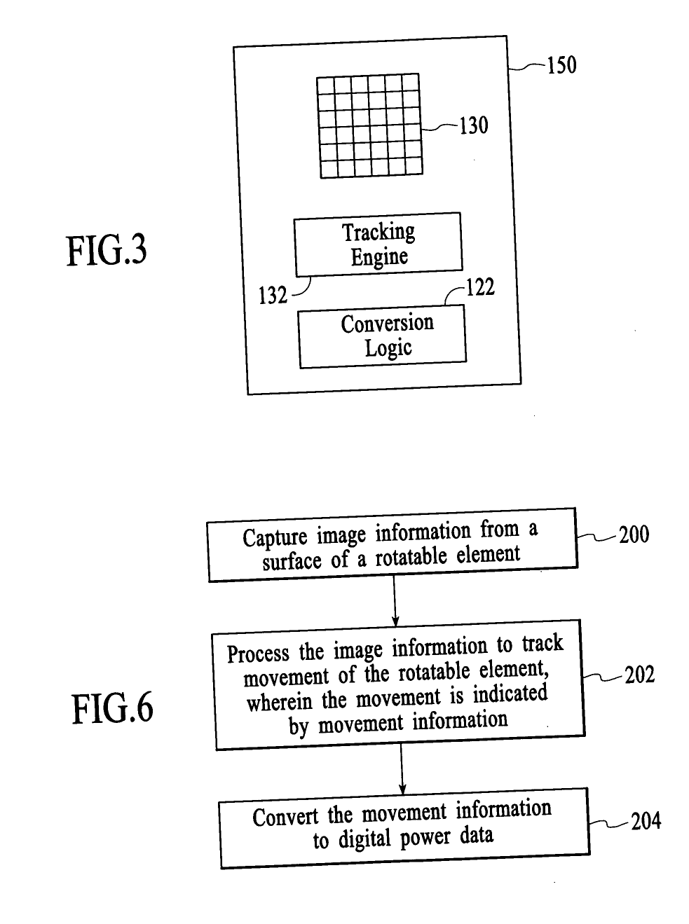

In an embodiment in accordance with the invention, some of the elements of the retrofit system 102 are fabricated onto a single integrated circuit (IC) chip. FIG. 3 depicts an example of an IC chip 150 that includes the image sensor 130, the tracking engine 132, and the conversion logic 122 from FIG. 2. In another embodiment in accordance with the invention, the communications port, or some portion thereof, can be incorporated into the IC chip.

There are many ways that the retrofit system 102 can be connected to the power meter 100. The particular way in which the retrofit system is connected to the power meter is implementation specific. In general, the retrofit system typically includes a structure that includes the optics 126, the movement tracking system 120, the conversion logic 122, and the communications port 124. The retrofit system can be connected outside of the enclosure structure of the power meter or inside of the enclosure structure of the power meter.

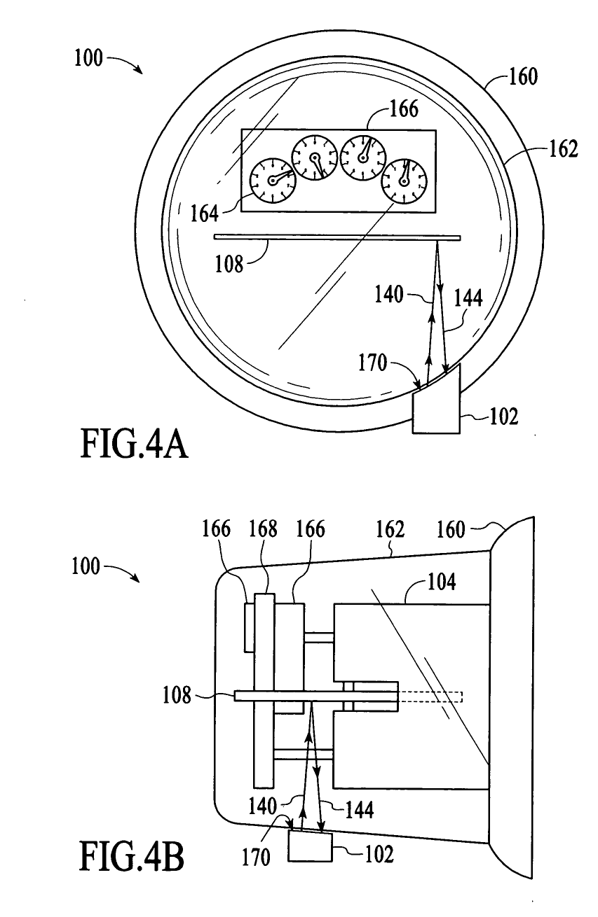

FIGS. 4A and 4B depict examples of the retrofit system 102 connected on the outside of an enclosure structure of a power meter 100. In the examples of FIGS. 4A and 4B, the enclosure structure is made up of a base 160 and a glass cover 162. FIG. 4A is a front view of the power meter that depicts dials 164 of a register 166, a disk 108 the base 160, the glass cover 162, and the retrofit system 102 attached to the outside of the glass cover. FIG. 4A also depicts an example light beam 140 and 144 that is output from the retrofit system, illuminates a spot on the disk, and reflects back to the retrofit system.

FIG. 4B is a side view of the power meter 100 from FIG. 4A that depicts the base 160, the cover glass 162, a frame 104, the disk 108, the register 166, a faceplate 168, and the retrofit system 102. As depicted in FIG. 4A, the retrofit system is attached to the outside of the glass cover. The retrofit system is connected to the outside of the glass cover such that a beam of light from the retrofit system can illuminate a spot on the disk and such that reflected light can be detected.

In the embodiments of FIGS. 4A and 4B, the retrofit system 102 includes a mounting surface 170 that is attached to the cover glass 162 by, for example, a transparent adhesive. In this example, the mounting surface is shaped complimentary to the shape of the cover glass. Other attachment techniques in accordance with the invention are also possible. Attaching the retrofit system to the outside of the cover glass is advantageous because it does not require opening of the cover glass.

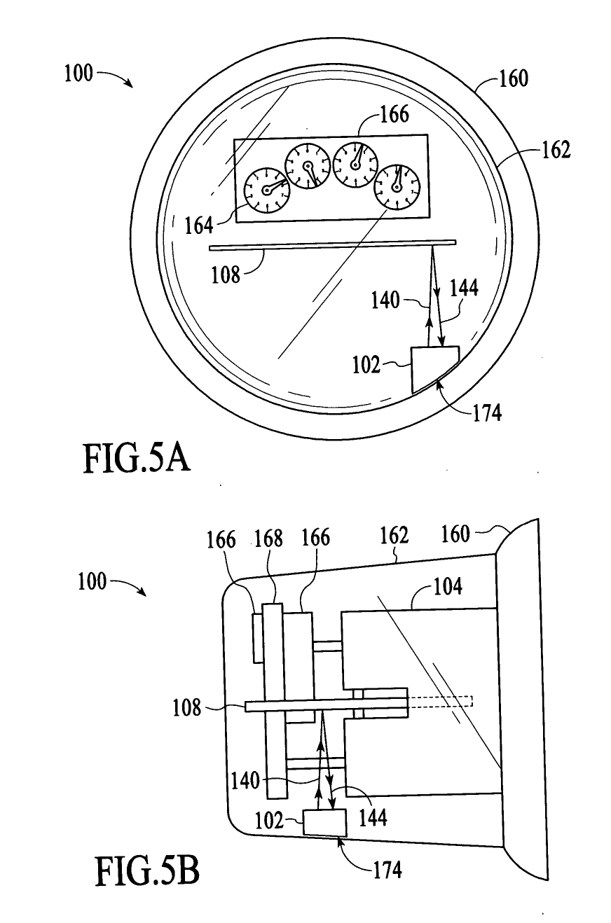

FIGS. 5A and 5B depict an example of the retrofit system 102 connected inside the cover glass 162 of a power meter 100. FIG. 5A is a front view of the power meter similar to FIG. 4A and FIG. 5B is a side view of the power meter similar to FIG. 4B. In the embodiment of FIGS. 5A and 5B, the retrofit system is attached directly to the inside of the cover glass 162. For example, the retrofit system includes a mounting surface 174 that is attached to the inside of the cover glass using an adhesive. In other inside the glass configurations, the retrofit system can be connected to any portion of the power meter. For example, the retrofit system can be connected to the frame 104, the base 160, or any other element or combination of elements.

Although the retrofit system 102 has been described with reference to a power meter 100 that utilizes a rotating disk 108, the technique can be applied to any meter with a moving element that can be imaged.

FIG. 6 is a process flow diagram of a method for obtaining data from a power meter that utilizes rotation of a rotatable element to measure power in accordance with the invention. At block 200, image information is captured from a surface of the rotatable element. At block 202, the image information is processed to track movement of the rotatable element, wherein the movement is indicated by movement information. At block 204, the movement information is converted to digital power data.

In an embodiment in accordance with the invention, the tracking engine is also configured to determine if a captured image frame is in focus or out of focus. This can be done, for example, by analyzing the sharpness and/or intensity of features of the image frame or by comparing aspects of the captured image frame to a reference image frame that is captured when the retrofit system is known to be in focus. Whether or not a captured image frame is in focus can be used to detect that the retrofit system is out of calibration and/or that the retrofit system has been tampered with. In another embodiment in accordance with the invention, a stored reference image frame is used to determine whether the retrofit system is imaging the disk or some other object that has been placed between the retrofit system and the disk (e.g., in an attempt to tamper with the meter readings).

Although specific embodiments in accordance with the invention have been described and illustrated, the invention is not to be limited to the specific forms or arrangements of parts so described and illustrated. The scope of the invention is to be defined by the claims appended hereto and their equivalents.

What is claimed is:

1. A power meter comprising:
a rotatable element that rotates in response to power consumption or power generation;
a movement tracking system comprising:
a light source configured to illuminate a spot on the rotatable element;
an image sensor configured to capture image information related to the rotatable element in response to light that reflects off the illuminated spot on the rotatable element;
a tracking engine configured to process the image information to track movement of the rotatable element and to output movement information; and
conversion logic configured to generate digital power data in response to the movement information.

2. The power meter of claim 1 wherein the image sensor comprises an array of distinct photodetectors, wherein each distinct photodetector generates light intensity information.

3. The power meter of claim 2 wherein the image information represents features on the surface of the rotatable element.

4. The power meter of claim 1 wherein the image sensor captures the image information as image frames and wherein the tracking engine is configured to correlate common features in the image frames to determine the magnitude of movement of the common features.

5. The power meter of claim 1 wherein the image sensor captures the image information as image frames and wherein the tracking engine is configured to correlate common features in the image frames to determine the magnitude and direction of movement of the common features.

6. The power meter of claim 1 wherein the image sensor and tracking engine are located on a single integrated circuit device.

7. The power meter of claim 1 further including an enclosure structure wherein the rotatable element and the movement tracking system are located within the enclosure structure.

8. The power meter of claim 1 further including an enclosure structure having a transparent portion wherein the rotatable element is located within the enclosure structure and wherein the movement tracking system is located outside of the enclosure structure and oriented such that light from the light source passes through the transparent portion of the enclosure structure to illuminate the spot on the rotatable element.

9. The power meter of claim 8 wherein the movement tracking system is incorporated into a retrofit system that is attached to the transparent portion of the enclosure structure.

10. A method for obtaining data from a power meter that utilizes rotation of a rotatable element to measure power, the method comprising:
capturing image information from a surface of the rotatable element;
processing the image information to track movement of the rotatable element, wherein the movement is indicated by movement information; and
converting the movement information to digital power data.

11. The method of claim 10 wherein capturing the image information comprises capturing image frames.

12. The method of claim 11 wherein processing the image information to track movement of the rotatable element comprises correlating common features in the image frames to determine the magnitude of movement of the common features.

13. The method of claim 11 wherein processing the image information to track movement of the rotatable element comprises correlating common features in the image frames to determine the magnitude and direction of movement of the common features.

14. The method of claim 10 wherein capturing the image information comprises illuminating a spot on the surface of the rotatable element and detecting light that reflects off of the illuminated spot.

15. The method of claim 10 further including determining whether or not the image information is in focus.

16. A retrofit system for obtaining data from a power meter that utilizes rotation of a rotatable element to measure power, the retrofit system comprising:
a light source configured to illuminate a spot on the rotatable element of the power meter;
an image sensor configured to capture image information related to the rotatable element in response to light that reflects off the illuminated spot on the rotatable element;
a tracking engine configured to use the image information to track movement of the rotatable element and to output movement information; and
conversion logic configured to generate digital power data in response to the movement information.

17. The retrofit system of claim 16 wherein the image sensor comprises an array of distinct photodetectors, wherein each distinct photodetector generates light intensity information and wherein the image information represents features on the surface of the rotatable element.

18. The retrofit system of claim 16 wherein the image sensor captures the image information as image frames and wherein the tracking engine is configured to correlate common features in the image frames to determine the magnitude of movement of the common features.

19. The retrofit system of claim 16 further comprising a retrofit structure, wherein the light source, image sensor, tracking engine, and conversion logic are secured to the retrofit structure.

20. The retrofit system of claim 19 wherein the package structure includes a mounting surface configured for attachment to a transparent portion of an enclosure structure of the power meter.
